(19) United States
(12) Patent Application Publication
(10) Pub. No.: US 2026/0033392 A1
(43) Pub. Date: Jan. 29, 2026

(54) HIGH BANDWIDTH MEMORY

(71) Applicant: Samsung Electronics Co., Ltd., Suwon-si (KR)

(72) Inventors: Hyeongmun KANG, Suwon-si (KR); Hongseok KIM, Suwon-si (KR); Jaeyong PARK, Suwon-si (KR)

(73) Assignee: Samsung Electronics Co., Ltd., Suwon-si (KR)

(21) Appl. No.: 19/174,411

(22) Filed: Apr. 9, 2025

(30) Foreign Application Priority Data
Jul. 24, 2024 (KR) 10-2024-0097893

(51) Int. Cl. H01L 25/065; H01L 23/00; H01L 23/498; H01L 23/538; H10B 80/00

(52) U.S. Cl. CPC H01L 25/0657; H01L 23/49816; H01L 23/5384; H01L 24/08; H10B 80/00; H01L 2224/08221; H01L 2225/06513; H01L 2225/06589

(57) ABSTRACT

A high bandwidth memory according to an example embodiment may include a base die, and a semiconductor stack on the base die. The semiconductor stack may include a plurality of semiconductor dies, which may be stacked in a vertical direction. Each of the plurality of semiconductor dies may include a plurality of memory dies arranged in a horizontal direction.

### CROSS-REFERENCE TO RELATED APPLICATION

This application claims priority to and the benefit of Korean Patent Application No. 10-2024-0097893 filed in the Korean Intellectual Property Office on Jul. 24, 2024, the entire contents of which are incorporated herein by reference.

### BACKGROUND

### (a) Field

The present disclosure relates to a high bandwidth memory.

### (b) Description of the Related Art

With the demands for smaller and lighter electronic devices, the semiconductor industry has been seeking to make semiconductor packages to be mounted in electronic devices smaller, lighter, and thinner while making semiconductor packages have higher speed, more functions, and higher capacity. Therefore, there is an increasing need for packaging technologies capable of storing more data and transmit data at a higher rate, and as such a packaging technology, high bandwidth memories (HBMs) which are formed by stacking a plurality of semiconductor chips have been developed and are being used.

A high bandwidth memory (HBM) may be manufactured by forming a memory stack of memory dies on a base die, and as the number of memory dies which are positioned on a base die increases, it may be possible to implement a high-performance high bandwidth memory (HBM). However, when the number of memory dies in a memory stack is increased, the height of the memory stack may become higher than a desired and/or alternatively predetermined height, and stack voids may occur at the interfaces between memory dies at the upper portion of the memory stack, warpage may occur in the memory stack, and/or heat accumulates inside the memory stack. Stack voids, warpage, and/or heat accumulation may degrade the performance of the high bandwidth memory (HBM).

In order to increase the number of memory dies that are positioned on one base die while keeping the height of a memory stack equal to or smaller than a desired and/or alternatively predetermined height, a high bandwidth memory (HBM) in which a plurality of memory stacks is disposed on one base die is being studied. However, a high bandwidth memory (HBM) with a plurality of memory stacks may be manufactured by repeatedly performing a memory die bonding process as many times as the increased number of memory dies, and accordingly, the turnaround time (TAT) may increase. Further, a high bandwidth memory (HBM) with a plurality of memory stacks may have a structure in which a molding material may be positioned in a region between the plurality of memory stacks which is a center region having a relatively significant influence on the heat dissipation characteristic of the high bandwidth memory (HBM), resulting in a deterioration in the heat dissipation characteristic of the high bandwidth memory (HBM).

### SUMMARY

The present disclosure relates to a high bandwidth memory (HBM) capable of being manufactured by performing singulation of semiconductor dies including two or more memory dies from a wafer including memory dies and stacking the singulated semiconductor dies on a base die.

A high bandwidth memory (HBM) according to an example embodiment may include a base die; and a semiconductor stack on the base die. The semiconductor stack may include a plurality of semiconductor dies, which may be stacked in a vertical direction, and each of the plurality of semiconductor dies may include a plurality of memory dies arranged in a horizontal direction.

A high bandwidth memory (HBM) according to an example embodiment may include a first semiconductor die including a first buffer die and a second buffer die that are arranged in a horizontal direction; and a semiconductor stack on the first semiconductor die. The semiconductor stack may include a plurality of second semiconductor dies stacked in a vertical direction. Each of the plurality of second semiconductor dies may include a first core die on the first buffer die and a second core die on the second buffer die.

A high bandwidth memory (HBM) according to an example embodiment may include a first semiconductor die including a first buffer die and a second buffer die, which may be arranged in a horizontal direction; and a semiconductor stack on the first semiconductor die. The semiconductor stack may include a plurality of second semiconductor dies stacked in a vertical direction, a plurality of inter-connection structures stacked alternately with the plurality of second semiconductor dies, and a molding material covering the semiconductor stack. The molding material may be on the first semiconductor die. Each of the plurality of second semiconductor dies may include a first core die on the first buffer die and a second core die on the second buffer die.

In example embodiments, by manufacturing a high bandwidth memory (HBM) by stacking in multiple layers a semiconductor die including two or more memory dies on a base die, it is possible to improve productivity by reducing the turnaround time (TAT) of a die bonding process, which increases linearly depending on the number of memory dies, while manufacturing a high-capacity high bandwidth memory (HBM).

As compared to a conventional high bandwidth memory (HBM), in which a plurality of memory stacks are disposed on a base die and the center regions between the plurality of memory stacks are covered by a molding material, a high bandwidth memory (HBM) according to example embodiments may have improve heat dissipation characteristics. In example embodiments, since the semiconductor die(s) are stacked on a base die and include two or more memory dies integrally formed based on a silicon material having a relatively excellent heat dissipation property, it may be possible to more efficiently dissipate heat from the center regions between the memory stacks and it may be possible to improve the heat dissipation characteristics of the high bandwidth memory (HBM).

### BRIEF DESCRIPTION OF THE DRAWINGS

FIG. 1 is a cross-sectional view illustrating a high bandwidth memory (HBM) of an example embodiment.

FIG. 2 is a plan view illustrating an upper surface of an example embodiment of the high bandwidth memory (HBM) of FIG. 1.

FIG. 3 is a plan view illustrating an upper surface of an example embodiment of the high bandwidth memory (HBM) of FIG. 1.

FIGS. 4 to 9 are cross-sectional views for explaining a method of manufacturing the high bandwidth memory (HBM) of FIG. 1.

FIG. 10 is a cross-sectional view illustrating a high bandwidth memory (HBM) of an example embodiment.

FIG. 11 is a plan view illustrating an upper surface of an example embodiment of the high bandwidth memory (HBM) of FIG. 10.

FIG. 12 is a plan view illustrating an upper surface of an example embodiment of the high bandwidth memory (HBM) of FIG. 10.

FIG. 13 is a cross-sectional view illustrating a high bandwidth memory (HBM) of an example embodiment.

FIGS. 14 to 19 are cross-sectional views for explaining a method of manufacturing the high bandwidth memory (HBM) of FIG. 13.

FIG. 20 is a cross-sectional view illustrating a high bandwidth memory (HBM) of an example embodiment.

FIGS. 21 to 25 are cross-sectional views for explaining a method of manufacturing the high bandwidth memory (HBM) of FIG. 20.

### DETAILED DESCRIPTION

In the following detailed description, only certain example embodiments of the present disclosure have been shown and described, simply by way of illustration. The present disclosure can be variously implemented and is not limited to the following example embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto.

Throughout this specification, when a part is referred to as being “connected” to another part, it may be directly connected to the other part, or may be connected to the other part indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, a high bandwidth memory (HBM) 100 according an example embodiment will be described with reference to the drawings.

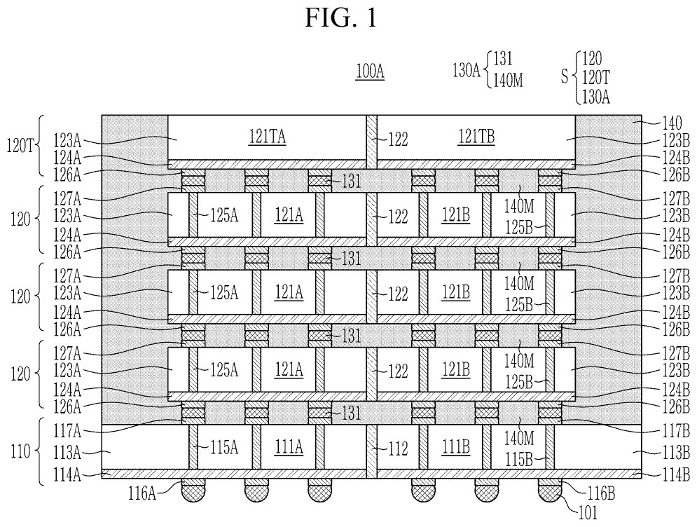

FIG. 1 is a cross-sectional view illustrating a high bandwidth memory (HBM) 100A of an example embodiment.

Referring to FIG. 1, the high bandwidth memory (HBM) 100A may include a base die (also referred to as a first semiconductor die or a base logic die) 110, a semiconductor stack S which includes second semiconductor dies 120 and 120T (wherein the uppermost second semiconductor die is denoted by the reference numeral “120T”; however, the reference numeral “120” may be used to describe the uppermost second semiconductor die), and a molding material 140. The high bandwidth memory (HBM) 100 is a high-performance 3D-stacked dynamic random access memory (DRAM). The high bandwidth memory (HBM) 100 has multiple memory channels through a semiconductor stack manufactured by vertically stacking memory dies so as to be able to simultaneously implement a shorter latency and a higher bandwidth as compared to conventional DRAM products. Compared to conventional DRAM products, the high bandwidth memory (HBM) may have a reduced total area on a substrate that is occupied by individual DRAMs, which may provide high bandwidth relative to an area. Compared to conventional DRAM products, the high bandwidth memory (HBM) may have reduced power consumption.

The base die 110 is disposed at the bottom of the high bandwidth memory (HBM) 100, and may be disposed between the semiconductor stack S and an external device. When data are exchanged between devices different from each other in the processing rate, processing unit, and usage time of data, data loss occurs due to the data processing rate difference, processing unit difference, and usage time difference between the individual devices. In order to limit and/or prevent such loss, the base die 110 is disposed between the semiconductor stack S and the external device, and information when data is exchanged between the semiconductor stack S and the external device is temporarily stored in the base die 110. When data is transmitted to the semiconductor stack S or data is received from the semiconductor stack S, the base die 110 sequences the data and sequentially passes the data.

The base die 110 may include a first buffer die 111A, a second buffer die 111B, and a first scribe lane 112. The first buffer die 111A and the second buffer die 111B may be arranged side by side in the horizontal direction. The first buffer die 111A, the second buffer die 111B, and the first scribe lane 112 may be a single component integrally formed of the same material inside a semiconductor die. The first buffer die 111A, the second buffer die 111B, and the first scribe lane 112 may be defined by dividing the plane of the base die 110. The first scribe lane 112 may be defined as a region between the first buffer die 111A and the second buffer die 111B. In general, a semiconductor wafer including buffer dies is divided into individual buffer dies by performing a singulation process along scribe lanes, and base dies consisting of individual buffer dies do not include scribe lanes. In contrast, one base die 110 according to the present disclosure may include two or more buffer dies 111A and 111B, and one or more first scribe lanes 112 which are positioned between the two or more buffer dies 111A and 111B and have not been subjected to singulation during a singulation process. The first scribe lane 112 may be thermally connected to the first buffer die 111A and the second buffer die 111B integrally formed.

In an example embodiment, the first buffer die 111A and the second buffer die 111B may be electrically disconnected from each other by the first scribe lane 112. In this case, the first buffer die 111A may be electrically connected to first core dies 121A and control the first core dies 121A, and may be electrically disconnected from second core dies 121B. The first buffer die 111A may temporarily store information when data are exchanged between the first core dies 121A and the external device. When transmitting data to the first core dies 121A or receiving data from the first core dies 121A, the first buffer die 111A may sequence the data and sequentially pass the data.

Also, the second buffer die 111B may be electrically connected to the second core dies 121B and control the second core dies 121B, and may be electrically disconnected from the first core dies 121A. The second buffer die 111B may temporarily store information when data are exchanged between the second core dies 121B and the external device. When transmitting data to the second core dies 121B or receiving data from the second core dies 121B, the second buffer die 111B may sequence the data and sequentially pass the data. The first buffer die 111A and the second buffer die 111B may be thermally connected to each other through the first scribe lane 112 formed integrally with the first buffer die 111A and the second buffer die 111B.

In an example embodiment, the first buffer die 111A and the second buffer die 111B may be electrically connected to each other through the first scribe lane 112. In this case, the first buffer die 111A and the second buffer die 111B may serve as one buffer die integrally formed, and the base die 110 may be referred to as the buffer die 110. The buffer die 110 may be electrically connected to the first core dies 121A, and be electrically connected to the second core dies 121B. The buffer die 110 may temporarily store information when data are exchanged between the first core dies 121A and the external device and between the second core dies 121B and the external device. When transmitting data to the first core dies 121A or the second core dies 121B, or receiving data from the first core dies 121A or the second core dies 121B, the buffer die 110 may sequence the data and sequentially pass the data. The first buffer die 111A and the second buffer die 111B inside the buffer die 110 may be thermally connected to each other through the first scribe lane 112. The first scribe laner 112 may be formed integrally with the first buffer die 111A and the second buffer die 111B.

Hereinafter, since the first buffer die 111A and the second buffer die 111B include the same configuration, the first buffer die 111A and the second buffer die 111B will be described together using a representative designation and a representative reference numeral without the suffixes “A” and “B” at the end of the reference symbol. For example, the first buffer die 111A and the second buffer die 111B will be described together as the buffer dies 111. A buffer die 111 may include a first die base 113, a first front side structure 114 below the first die base 113, first through-silicon vias 115 in the first die base 113, first connection pads 116 below the first front side structure 114, and first bonding pads 117 on the first die base 113.

The first die base 113 may be disposed with its front side facing downward. The first die base 113 may be a die formed from a wafer. In an example embodiment, the first die base 113 may comprise silicon or any other semiconductor material.

The first front side structure 114 may be positioned on the first die base 113. The first front side structure 114 may include an active layer and a wiring layer. The active layer may be positioned on the front side of the first die base 113. The active layer may include an integrated circuit structure having integrated circuit regions. In an example embodiment, the integrated circuit structure may include at least one of active devices and passive devices. In an example embodiment, the integrated circuit structure may include a gate structure, a source region, and a drain region. In an example embodiment, the integrated circuit structure may include at least one of transistors, diodes, capacitors, inductors, and resistors. The wiring layer may be disposed on the active layer. The wiring layer may include wiring lines for signals, wiring lines for power, contact plugs, and an inter-metal dielectric (IMD).

The first through-silicon vias 115 may be disposed inside the first die base 113. Each of the first through-silicon vias 115 may be disposed between the active layer or wiring layer of the first front side structure 114 and the corresponding first bonding pad 117 of the first bonding pads 117. Each of the first through-silicon vias 115 may electrically connect the active layer or wiring layer of the first front side structure 114 to the corresponding first bonding pad 117 of the first bonding pads 117. In an example embodiment, the first through-silicon vias 115 may comprise at least one of tungsten, aluminum, copper, and alloys thereof.

Each of the first connection pads 116 may be disposed between the wiring layer of the first front side structure 114 and the corresponding external connection member 101 of the external connection members 101. Each of the first connection pads 116 may electrically connect the wiring layer of the first front side structure 114 to the corresponding external connection member 101 of the external connection members 101. In an example embodiment, the first connection pads 116 may comprise at least one of copper, aluminum, tungsten, nickel, gold, tin, titanium, and alloys thereof.

The first bonding pads 117 may be disposed on the back side of the first die base 113. Each of the first bonding pads 117 may be disposed between the corresponding first through-silicon via 115 of the first through-silicon vias 115 and the corresponding first connection member 131 of the first connection members 131. Each of the first bonding pads 117 may electrically connect the corresponding first through-silicon via 115 of the first through-silicon vias 115 to the corresponding first connection member 131 of the first connection members 131. In an example embodiment, the first bonding pads 117 may comprise at least one of copper, aluminum, tungsten, nickel, gold, tin, titanium, and alloys thereof.

Each of the external connection members 101 may be disposed between the corresponding first connection pad 116 of the first connection pads 116 and the external device. Each of the external connection members 101 may electrically connect the corresponding first connection pad 116 of the first connection pads 116 to the external device. In an example embodiment, the external connection members 101 may include micro bumps or solder balls. In an example embodiment, the external connection members 101 may comprise at least one of tin, silver, lead, nickel, copper, and alloys thereof.

The semiconductor stack S may be disposed on the base die 110. The semiconductor stack S may include the second semiconductor dies 120 and inter-connection structures 130A. The second semiconductor dies 120 may be stacked sequentially in the vertical direction on the base die 110. Each of the inter-connection structures 130A may be disposed between the base die 110 and a second semiconductor die 120 or between neighboring second semiconductor dies 120 of the second semiconductor dies 120.

Each of the second semiconductor dies 120 may include a first core die (a first memory die) 121A, a second core die (a second memory die) 121B, and a second scribe lane 122. The first core die 121A and the second core die 121B may be arranged side by side in the horizontal direction. The first core die 121A, the second core die 121B, and the second scribe lane 122 may be a single component integrally formed of the same material inside a semiconductor die. The first core die 121A, the second core die 121B, and the second scribe lane 122 may be defined by dividing the plane of a second semiconductor die 120. The second scribe lane 122 may be defined as a region between the first core die 121A and the second core die 121B. In general, a semiconductor wafer including core dies is divided into individual core dies by performing a singulation process along scribe lanes, and semiconductor dies consisting of individual core dies do not include scribe lanes. In contrast, one second semiconductor die 120 according to the present disclosure may include two or more core dies 121A and 121B, and one or more second scribe lanes 122 which are positioned between the two or more core dies 121A and 121B and have not been subjected to singulation during a singulation process. The second scribe lane 122 may be thermally connected to the first core die 121A and the second core die 121B integrally formed.

The first core die 121A and the second core die 121B may be electrically disconnected from each other by the second scribe lane 122. The first core die 121A and the second core die 121B may be thermally connected to each other through the second scribe lane 122 formed integrally with the first core die 121A and the second core die 121B. Each of the first core die 121A and the second core die 121B may include a DRAM.

Hereinafter, since the first core die 121A and the second core die 121B include the same configuration, the first core die 121A and the second core die 121B will be described together using a representative designation and a representative reference numeral without the suffixes “A” and “B” at the end of the reference symbol. For example, the first core die 121A and the second core die 121B will be described together as the core dies 121. A core die 121 may include a second die base 123, a second front side structure 124 below the second die base 123, second through-silicon vias 125 in the second die base 123, second connection pads 126 below the second front side structure 124, and second bonding pads 127 on the second die base 123. The core die 121T which is disposed at the top of the semiconductor stack S may include a second die base 123, a second front side structure 124 below the second die base 123, and second connection pads 126 below the second front side structure 124.

The second die base 123 may be disposed such that its front side faces the base die 110. The second die base 123 may be a die formed from a wafer. In an example embodiment, the second die base 123 may comprise silicon or any other semiconductor material.

The second front side structure 124 may be positioned on the second die base 123. The second front side structure 124 may include an active layer and a wiring layer. The active layer may be positioned on the front side of the second die base 123. The active layer may include an integrated circuit structure having integrated circuit regions. In an example embodiment, the integrated circuit structure may include at least one of active devices and passive devices. In an example embodiment, the integrated circuit structure may include a gate structure, a source region, and a drain region. In an example embodiment, the integrated circuit structure may include at least one of transistors, diodes, capacitors, inductors, and resistors. The wiring layer may be disposed on the active layer. The wiring layer may include wiring lines for signals, wiring lines for power, contact plugs, and an inter-metal dielectric (IMD).

The second through-silicon vias 125 may be disposed inside the second die base 123. Each of the second through-silicon vias 125 may be disposed between the active layer or wiring layer of the second front side structure 124 and the corresponding second bonding pad 127 of the second bonding pads 127. Each of he second through-silicon vias 125 may electrically connect the active layer or wiring layer of the second front side structure 124 to the corresponding second bonding pad 127 of the second bonding pads 127. In an example embodiment, the second through-silicon vias 125 may comprise at least one of tungsten, aluminum, copper, and alloys thereof.

Each of the second connection pads 126 may be disposed between the wiring layer of the second front side structure 124 and the corresponding connection member 131 of the connection members 131. Each of the second connection pads 126 may electrically connect the wiring layer of the second front side structure 124 to the corresponding connection member 131 of the connection members 131. In an example embodiment, the second connection pads 126 may comprise at least one of copper, aluminum, tungsten, nickel, gold, tin, titanium, and alloys thereof.

The second bonding pads 127 may be disposed on the back side of the second die base 123. Each of he second bonding pads 127 may be disposed between the corresponding second through-silicon via 125 of the second through-silicon vias 125 and the corresponding connection member 131 of the connection members 131. Each of the second bonding pads 127 may electrically connect the corresponding second through-silicon via 125 of the second through-silicon vias 125 to the corresponding connection member 131 of the connection members 131. In an example embodiment, the second bonding pads 127 may comprise at least one of copper, aluminum, tungsten, nickel, gold, tin, titanium, and alloys thereof.

The inter-connection structures 130A may be stacked alternately with the second semiconductor dies 120 in the vertical direction inside the semiconductor stack S. Each of the inter-connection structures 130A may be disposed between the base die 110 and a second semiconductor die 120 or between neighboring second semiconductor dies 120. Each of the inter-connection structures 130A may include connection members 131 and an insulating member 140M.

Each of the connection members 131 may be disposed between the corresponding first bonding pad 117 of the first bonding pads 117 of a buffer die 111 and the corresponding second connection pads 126 of the second connection pads 126 of a lowermost core die 121 or between the corresponding second bonding pad 127 of the second bonding pads 127 of a core die 121 and the corresponding second connection pad 126 of the second connection pads 126 of a neighboring core die 121. Each of the connection members 131 may electrically connect the corresponding second connection pad 126 of the second connection pads 126 of a lowermost core die 121 to the corresponding of the first bonding pad 117 of a buffer die 111, or may electrically connect the corresponding second connection pad 126 of the second connection pads 126 of a core die 121 to the corresponding second bonding pad 127 of the second bonding pads 127 of a neighboring core die 121. In an example embodiment, the connection members 131 may include micro bumps. In an example embodiment, the connection members 131 may comprise at least one of tin, silver, lead, nickel, copper, and alloys thereof.

Each of the insulating members 140M may be disposed between a base die (a first semiconductor die) 110 and a second semiconductor die 120, or between neighboring second semiconductor dies 120. The insulating member 140M between the base die 110 and the second semiconductor dies 120 may surround and insulate the first bonding pads 117, the connection members 131, and the second connection pads 126 of the second semiconductor dies 120. The insulating member 140M between neighboring second semiconductor dies 120 may surround and insulate the second bonding pads 127, the connection members 131, and the second connection pads 126. In an example embodiment, the insulating members 140M may include molded underfill (MUF). The MUF may comprise the same material as that of the molding material 140 and be formed integrally with the molding material 140. In an example embodiment, the insulating members 140M may be an epoxy molding compound (EMC).

The molding material 140 may be disposed on the base die 110 and encapsulate the semiconductor stack S. The molding material 140 serves to protect and insulate the semiconductor stack S. In an example embodiment, the molding material 140 may be an epoxy molding compound (EMC).

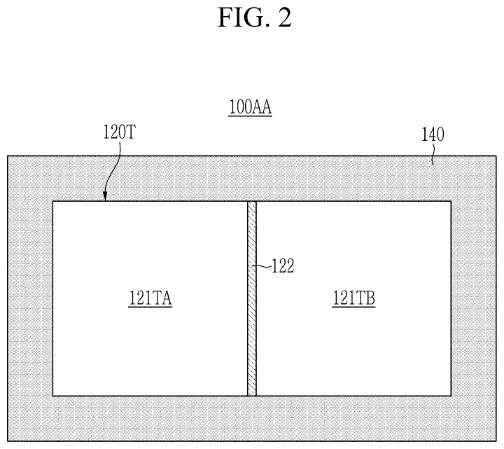

FIG. 2 is a plan view illustrating an upper surface 100AA of an example embodiment of the high bandwidth memory (HBM) 100A of FIG. 1.

Referring to FIG. 2, a second semiconductor die 120 (or 120T) of the semiconductor stack S may include a first core die 121A (or 121TA), a second scribe lane 122, and a second core die 121B (or 121TB). The first core die 121A (or 121TA), the second scribe lane 122, and the second core die 121B (or 121TB) inside the second semiconductor die 120 (or 120T) may be arranged in a line. The second scribe lane 122 may be positioned between the first core die 121A (or 121TA) and the second core die 121B (or 121TB). The first core die 121A (or 121TA) and the second core die 121B (or 121TB) may be electrically disconnected from each other. The first core die 121A (or 121TA), the second core die 121B (or 121TB), and the second scribe lane 122 inside the second semiconductor die 120 (or 120T) may be thermally connected to each other.

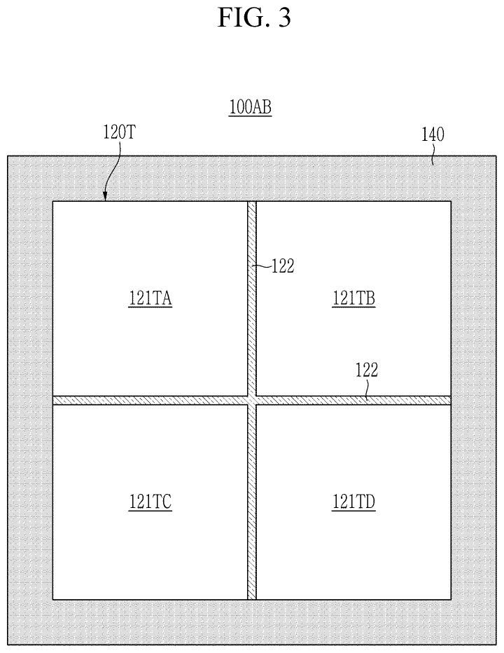

FIG. 3 is a plan view illustrating an upper surface 100AB of an example embodiment of the high bandwidth memory (HBM) 100A of FIG. 1.

Referring to FIG. 3, a second semiconductor die 120 (or 120T) of the semiconductor stack S may include a first core die 121A (or 121TA), a second core die 121B (or 121TB), a third core die 121C (or 121TC), a fourth core die 121D (or 121TD), and second scribe lanes 122. The first core die 121A (or 121TA), the second core die 121B (or 121TB), the third core die 121C (or 121TC), and the fourth core die 121D (or 121TD) inside the second semiconductor die 120 (or 120T) may be arranged in two rows and two columns. Each of the second scribe lanes 122 extending in a first horizontal direction or a second horizontal direction perpendicular to the first horizontal direction may be interposed among the first core die 121A (or 121TA), the second core die 121B (or 121TB), the third core die 121C (or 121TC), and the fourth core die 121D (or 121TD). The first core die 121A (or 121TA), the second core die 121B (or 121TB), the third core die 121C (or 121TC), and the fourth core die 121D (or 121TD) may be electrically disconnected from each other. The first core die 121A (or 121TA), the second core die 121B (or 121TB), the third core die 121C (or 121TC), the fourth core die 121D (or 121TD), and the second scribe lanes 122 extending in the first horizontal direction or the second horizontal direction may be thermally connected.

The high bandwidth memory (HBM) according to the present disclosure may be manufactured by stacking the second semiconductor dies 120, including two or more core dies 121 integrally formed based on a silicon material having a relatively excellent heat dissipation property as compared to the molding material, on the base die 110. Accordingly, as compared to a conventional high bandwidth memory (HBM) in which a plurality of semiconductor stacks is disposed on a base die and the center regions between the plurality of semiconductor stacks are covered by a molding material, the high bandwidth memory (HBM) according to the present disclosure has higher capacity, and can more efficiently dissipate heat from the center regions, which may have a relatively significant influence on the heat dissipation characteristic of the high bandwidth memory (HBM).

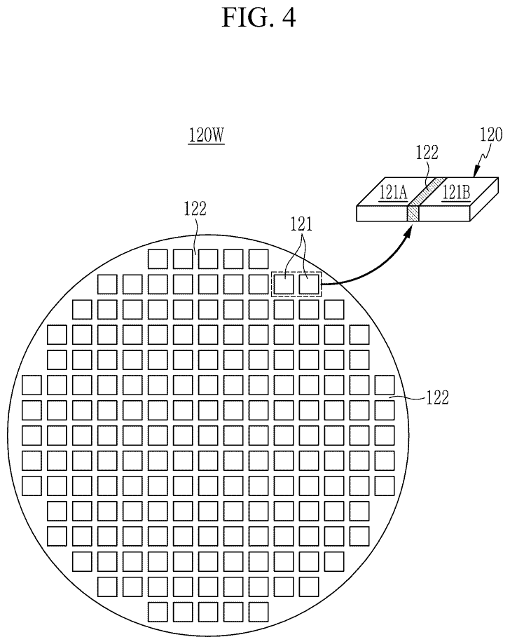

FIGS. 4 to 9 are cross-sectional views for explaining a method of manufacturing the high bandwidth memory (HBM) 100A of FIG. 1.

FIG. 4 is a cross-sectional view illustrating an operation of obtaining second semiconductor dies 120 by performing singulation on a semiconductor wafer 120W.

Referring to FIG. 4, the semiconductor wafer 120W may include core dies 121 and second scribe lanes 122. The core dies 121 and the second scribe lanes 122 may be defined by dividing the plane of the semiconductor wafer 120W. The semiconductor wafer 120W may be divided into second semiconductor dies 120 by performing a singulation process. A second semiconductor die 120 may include a plurality of core dies 121 and one or more second scribe lanes 122. In FIG. 4, it is shown that a second semiconductor die 120 includes two core dies 121A and 121B and one second scribe lane 122; however, the present disclosure is not limited thereto, and an individual second semiconductor die 120 including more core dies and scribe lanes may be included in the scope of the present disclosure.

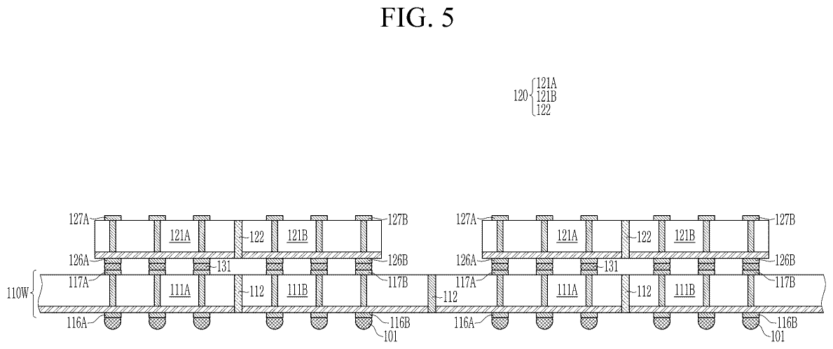

FIG. 5 is a cross-sectional view illustrating an operation of mounting second semiconductor dies 120 on a semiconductor wafer 110W.

Referring to FIG. 5, the second semiconductor dies 120 may be mounted on the semiconductor wafer 110W. The second semiconductor dies 120 may be mounted on the basis of a chip-on-wafer (CoW) process technology. In an example embodiment, the second semiconductor dies 120 may be mounted on the semiconductor wafer 110W by performing a flip-chip bonding process.

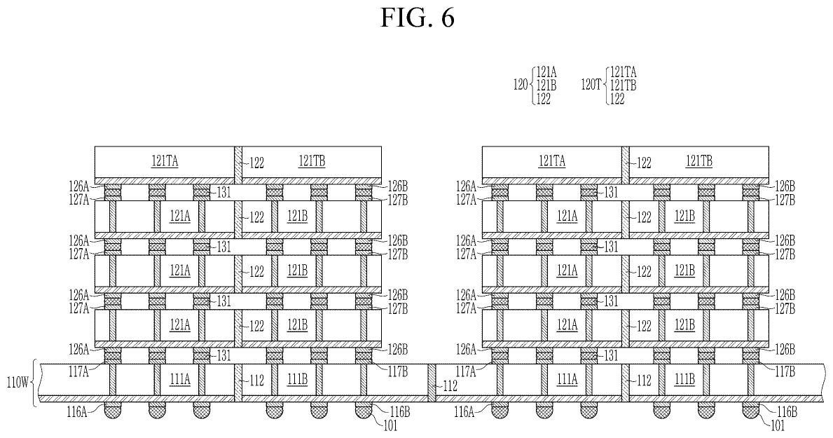

FIG. 6 is a cross-sectional view illustrating an operation of stacking second semiconductor dies 120.

Referring to FIG. 6, the second semiconductor dies 120 may be stacked sequentially from the bottom. In an example embodiment, the second semiconductor dies 120 may be stacked by performing a flip-chip bonding process.

By manufacturing the high bandwidth memory (HBM) by stacking the second semiconductor dies 120 including two or more core dies 121 as described above, it is possible to improve productivity by reducing the turnaround time (TAT) of a die bonding process, which increases linearly depending on the number of core dies 121, while manufacturing the high-capacity high bandwidth memory (HBM).

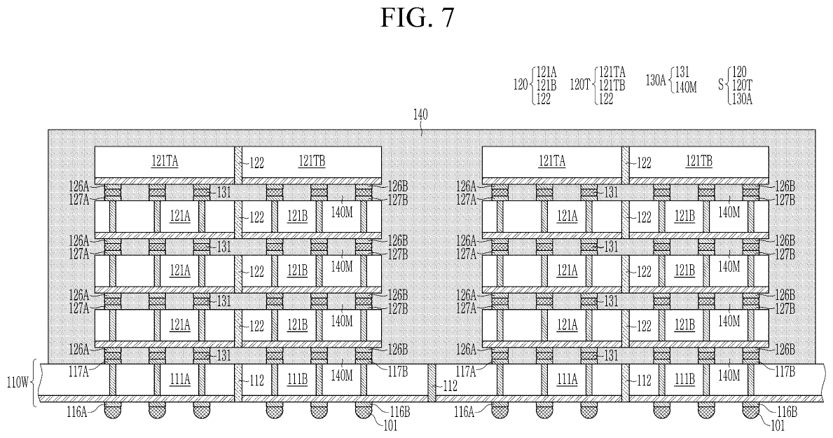

FIG. 7 is a cross-sectional view illustrating an operation of encapsulating semiconductor stacks S on the semiconductor wafer 110W.

Referring to FIG. 7, the semiconductor stacks S may be encapsulated on the semiconductor wafer 110W with the molding material 140. While the encapsulating process is performed, the insulating member (MUF) 140M may be filled between the base die (a first semiconductor die) 110 and a second semiconductor die 120 or between neighboring second semiconductor dies 120. As an example embodiment, the process of performing encapsulating with the molding material 140 may include a compression molding or transfer molding process. In an example embodiment, the molding material 140 may comprise an epoxy molding compound (EMC).

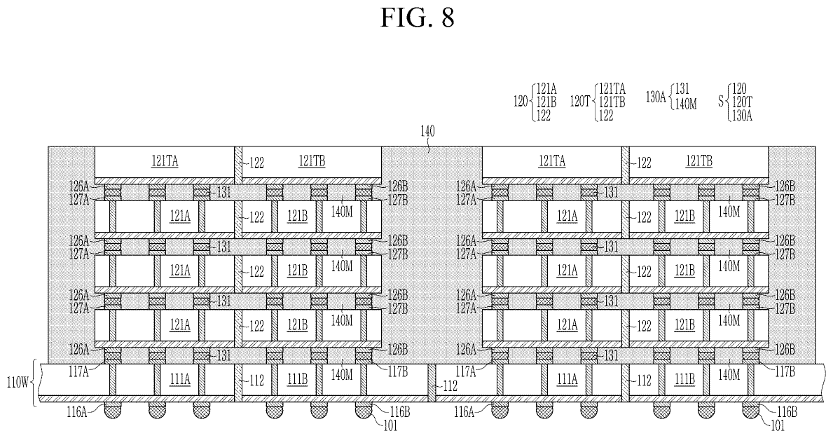

FIG. 8 is a cross-sectional view illustrating an operation of performing a chemical mechanical planarization (CMP) process on the molding material 140.

Referring to FIG. 8, the upper surface of the molding material 140 may be planarized by performing a chemical mechanical planarization (CMP) process. After the chemical mechanical planarization (CMP) process is performed, the upper surface of the second semiconductor die 120T may be exposed. Heat generated by the base die 110 and the second semiconductor dies 120 may be dissipated from the exposed upper surface of the second semiconductor die 120T.

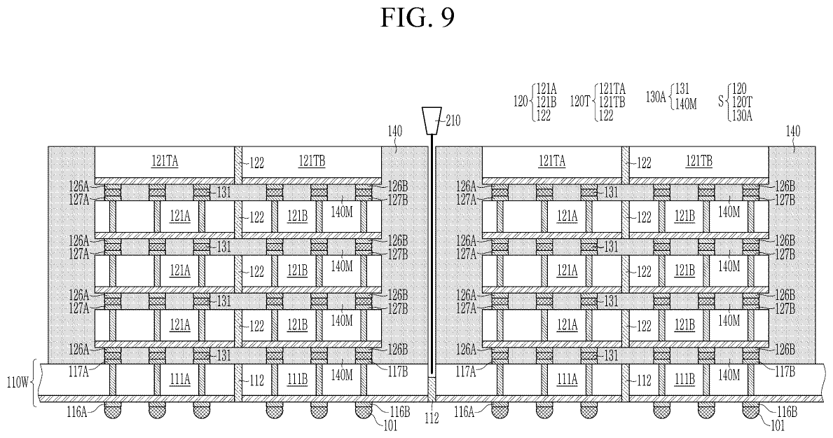

FIG. 9 is a cross-sectional view illustrating a process of singulation of the high bandwidth memory (HBM) 100A from the reconfigured semiconductor wafer 110W.

Referring to FIG. 9, singulation of the high bandwidth memory (HBM) 100A from the semiconductor wafer 110W may be performed using singulation equipment 210. In an example embodiment, as the singulation equipment 210, a blade, a laser, or plasma etching equipment may be used.

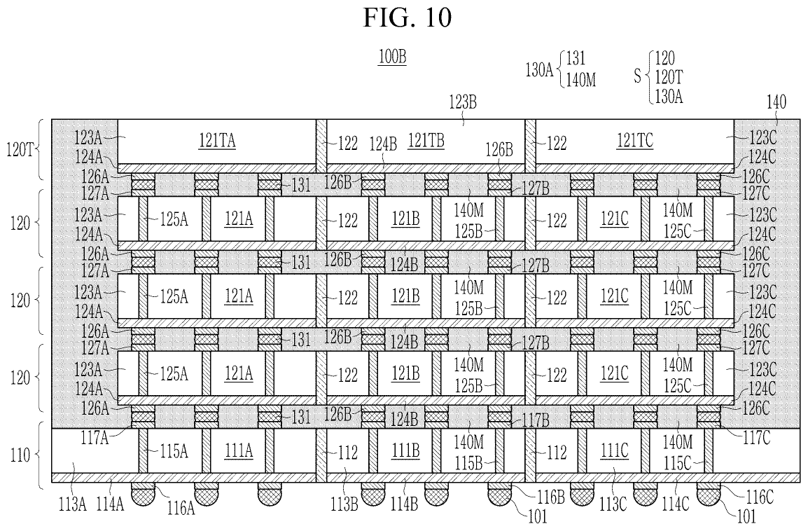

FIG. 10 is a cross-sectional view illustrating a high bandwidth memory (HBM) 100B of an example embodiment.

Referring to FIG. 10, the high bandwidth memory (HBM) 100B may include a base die (a first semiconductor die) 110, a semiconductor stack S including second semiconductor dies 120 and 120T, and a molding material 140.

The base die 110 may include a first buffer die 111A, a second buffer die 111B, a third buffer die 111C, and first scribe lanes 112. The first buffer die 111A, the second buffer die 111B, and the third buffer die 111C may be arranged side by side in the horizontal direction. The first buffer die 111A, the second buffer die 111B, the third buffer die 111C, and the first scribe lanes 112 may be a single component integrally formed of the same material inside a semiconductor die. The first buffer die 111A, the second buffer die 111B, the third buffer die 111C, and the first scribe lanes 112 may be defined by dividing the plane of the base die 110. Each of the first scribe lanes 112 may be defined as a region between the first buffer die 111A and the second buffer die 111B, or between the second buffer die 111B and the third buffer die 111C. One base die 110 according to the present disclosure may include three or more buffer dies 111A, 111B, and 111C, and the first scribe lanes 112 which are positioned among the three or more buffer dies 111A, 111B, and 111C and have not been subjected to singulation during a singulation process. A first scribe lane 112 may be thermally connected to the first buffer die 111A, the second buffer die 111B, and the third buffer die 111C integrally formed.

In an example embodiment, the first buffer die 111A, the second buffer die 111B, and the third buffer die 111C may be electrically disconnected from each other by each of the first scribe lanes 112. In this case, the first buffer die 111A may be electrically connected to first core dies 121A and control the first core dies 121A, and may be electrically disconnected from second core dies 121B and third core dies 121C. The second buffer die 111B may be electrically connected to the second core dies 121B and control the second core dies 121B, and may be electrically disconnected from the first core dies 121A and the third core dies 121C.

The third buffer die 111C may be electrically connected to the third core dies 121C and control the third core dies 121C, and may be electrically disconnected from the first core dies 121A and the second core dies 121B. The third buffer die 111C may temporarily store information when data are exchanged between the third core dies 121C and an external device. When transmitting data to the third core dies 121C or receiving data from the third core dies 121C, the third buffer die 111C may sequence the data and sequentially pass the data.

The first buffer die 111A, the second buffer die 111B, and the third buffer die 111C may be thermally connected to one another through the first scribe lanes 112 formed integrally with the first buffer die 111A, the second buffer die 111B, and the third buffer die 111C.

In an example embodiment, the first buffer die 111A, the second buffer die 111B, and the third buffer die 111C may be electrically connected to one another through a first scribe lane 112. In this case, the first buffer die 111A, the second buffer die 111B, and the third buffer die 111C may serve as one buffer die integrally formed, and the base die 110 may be referred to as the buffer die 110. The buffer die 110 may be electrically connected to the first core dies 121A, the second core dies 121B, and the third core dies 121C. The buffer die 110 may temporarily store information when data are exchanged between the first core dies 121A and the external device, between the second core dies 121B and the external device, or between the third core dies 121C and the external device. When transmitting data to the first core dies 121A, the second core dies 121B, or the third core dies 121C, or receiving data from the first core dies 121A, the second core dies 121B, or the third core dies 121C, the buffer die 110 may sequence the data and sequentially pass the data.

The semiconductor stack S may be disposed on the base die 110. The semiconductor stack S may include the second semiconductor dies 120 and inter-connection structures 130A. The second semiconductor dies 120 may be stacked sequentially in the vertical direction on the base die 110. Each of the inter-connection structures 130A may be disposed between the base die 110 and a second semiconductor die 120 or between second semiconductor dies 120.

Each of the second semiconductor dies 120 may include a first core die (a first memory die) 121A, a second core die (a second memory die) 121B, a third core die (a third memory die) 121C and a second scribe lane 122. The first core die 121A, the second core die 121B, and the third core die 121C may be arranged side by side in the horizontal direction. The first core die 121A, the second core die 121B, the third core die 121C, and the second scribe lane 122 may be a single component integrally formed of the same material inside a semiconductor die. The first core die 121A, the second core die 121B, the third core die 121C, and the second scribe lane 122 may be defined by dividing the plane of a second semiconductor die 120. The second scribe lane 122 may be defined as a region between the first core die 121A and the second core die 121B or between the second core die 121B and the third core die 121C. One second semiconductor die 120 according to the present disclosure may include three or more core dies 121A, 121B, and 121C, and the second scribe lanes 122 which are positioned between the three or more core dies 121A, 121B, and 121C and have not been subjected to singulation during a singulation process. The second scribe lanes 122 may be thermally connected to the first core die 121A, the second core die 121B, and the third core die 121C integrally formed.

The first core die 121A, the second core die 121B, and the third core dies 121C may be electrically disconnected from one another by the second scribe lanes 122. The first core die 121A, the second core die 121B, and the third core die 121C may be thermally connected to one another through the second scribe lanes 122 formed integrally with the first core die 121A, the second core die 121B, and the third core die 121C. Each of the first core die 121A, the second core die 121B, and the third core die 121C may include a DRAM.

In respect to the high bandwidth memory (HBM) 100B of FIG. 10 other than the above contents, the contents described with respect to the high bandwidth memory (HBM) 100A of FIG. 1 may be applied.

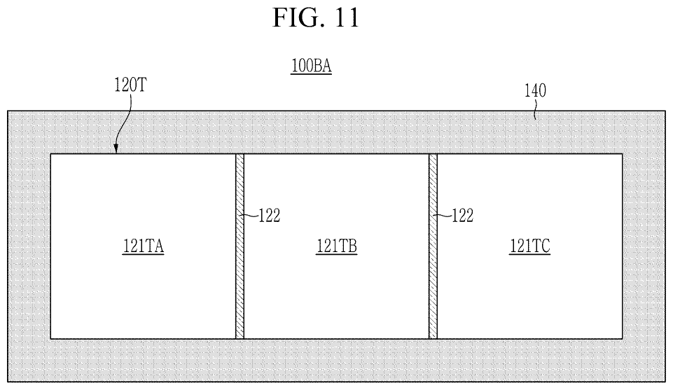

FIG. 11 is a plan view illustrating an upper surface 100BA of an example embodiment of the high bandwidth memory (HBM) 100B of FIG. 10.

Referring to FIG. 11, a second semiconductor die 120 (or 120T) of the semiconductor stack S may include a first core die 121A (or 121TA), a second core die 121B (or 121TB), a third core die 121C (or 121TC), and second scribe lanes 122. The first core die 121A (or 121TA), the second core die 121B (or 121TB), the third core die 121C (or 121TC), and the second scribe lanes 122 inside the second semiconductor die 120 (or 120T) may be arranged in a line. In FIG. 11, it is shown that a second semiconductor die 120 (or 120T) includes three core dies 121A, 121B, and 121C (or 121TA, 121TB, and 121TC) and two second scribe lanes 122; however, the present disclosure is not limited thereto, and a second semiconductor die 120 (or 120T) including more core dies and scribe lanes may be included in the scope of the present disclosure. In an example embodiment, a second semiconductor die 120 (or 120T) may include a plurality of core dies 121 that is arranged in a line, and one or more scribe lanes that are arranged alternately with the plurality of core dies in the horizontal direction. The plurality of core dies 121 may be electrically disconnected from one another. The plurality of core dies and one or more scribe lanes inside a second semiconductor die 120 (or 120T) may be thermally connected.

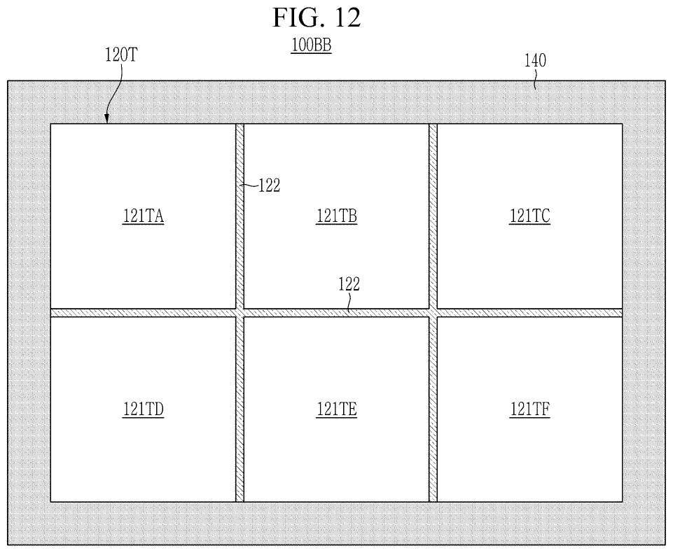

FIG. 12 is a plan view illustrating an upper surface 100BB of an example embodiment of the high bandwidth memory (HBM) 100B of FIG. 10.

Referring to FIG. 12, a second semiconductor die 120 (or 120T) of the semiconductor stack S may include a first core die 121A (or 121TA), a second core die 121B (or 121TB), a third core die 121C (or 121TC), a fourth core die 121D (or 121TD), a fifth core die 121E (or 121TE), a sixth core die 121F (or 121TF), and second scribe lanes 122. The first core die 121A (or 121TA), the second core die 121B (or 121TB), the third core die 121C (or 121TC), the fourth core die 121D (or 121TD), the fifth core die 121E (or 121TE), and the sixth core die 121F (or 121TF) inside the second semiconductor die 120 (or 120T) may be arranged in two rows and three columns. In FIG. 12, it is shown that a second semiconductor die 120 (or 120T) includes six core dies 121A, 121B, 121C, 121D, 121E, and 121F (or 121TA, 121TB, 121TC, 121TD, 121TE, and 121TF), a second scribe lane 122 that extends in a first horizontal direction, and second scribe lanes 122 that extend in a second horizontal direction perpendicular to the first horizontal direction; however, the present disclosure is not limited thereto, and a second semiconductor die 120 including more core dies and scribe lanes may be included in the scope of the present disclosure. In an example embodiment, a second semiconductor die 120 (or 120T) may include a plurality of core dies 121 that is arranged in a plurality of lines, and a plurality of scribe lanes that is arranged alternately with the plurality of core dies in the first horizontal direction or the second horizontal direction. The plurality of core dies 121 may be electrically disconnected from one another. The plurality of core dies and the plurality of scribe lanes inside a second semiconductor die 120 (or 120T) may be thermally connected.

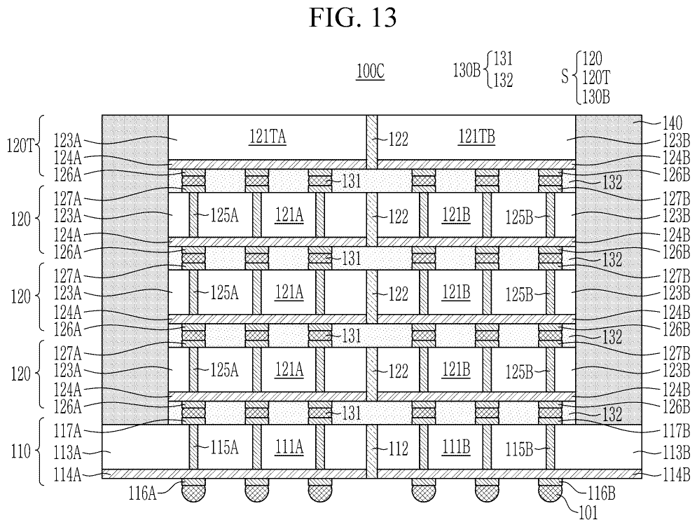

FIG. 13 is a cross-sectional view illustrating a high bandwidth memory (HBM) 100C of an example embodiment.

Referring to FIG. 13, a semiconductor stack S of the high bandwidth memory (HBM) 100C may include second semiconductor dies 120 and inter-connection structures 130B. Each of the inter-connection structures 130B may be disposed between the base die 110 and a second semiconductor die 120 or between neighboring second semiconductor dies 120. Each of the inter-connection structures 130B may include connection members 131 and insulating members 132.

Each of the insulating members 132 may be disposed between the base die (a first semiconductor die) 110 and a second semiconductor die 120 or between neighboring second semiconductor dies 120. The insulating member 132 between the base die 110 and a second semiconductor die 120 may surround and insulate the first bonding pads 117, the connection members 131, and the second connection pads 126 of the second semiconductor die 120. The insulating member 132 between neighboring second semiconductor dies 120 may surround and insulate the second bonding pads 127, the connection members 131, and the second connection pads 126. In an example embodiment, the insulating members 132 may include non-conductive films (NCFs).

In respect to the high bandwidth memory (HBM) 100C of FIG. 13 other than the above contents, the contents described with respect to the high bandwidth memory (HBM) 100A of FIG. 1 may be applied.

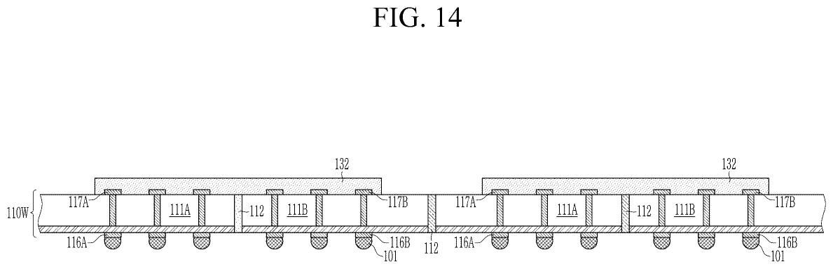

FIGS. 14 to 19 are cross-sectional views for explaining a method of manufacturing the high bandwidth memory (HBM) 100C of FIG. 13.

FIG. 14 is a cross-sectional view illustrating an operation of attaching insulating members 132 on the semiconductor wafer 110W.

Referring to FIG. 14, an insulating member 132 (e.g., non-conductive film (NCF)) may be attached on the semiconductor wafer 110W.

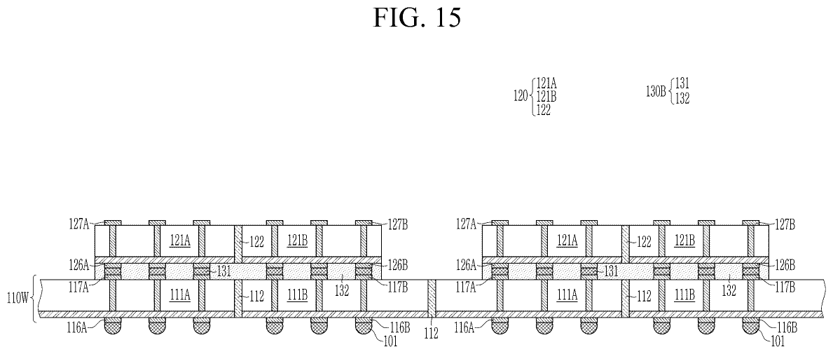

FIG. 15 is a cross-sectional view illustrating an operation of mounting second semiconductor dies 120 on the semiconductor wafer 110W.

Referring to FIG. 15, second semiconductor dies 120 may be mounted on the semiconductor wafer 110W. The connection members 131 connected to the second connection pads 126 of a second semiconductor die 120 may pass through the insulating member 132 and be connected to the first bonding pads 117 of the semiconductor wafer 110W. The insulating member 132 may protect and insulate the first bonding pads 117, the connection members 131, and the second connection pads 126 of the second semiconductor die 120. The second semiconductor die 120 may be mounted on the basis of a chip-on-wafer (CoW) process technology. In an example embodiment, the second semiconductor dies 120 may be mounted on the semiconductor wafer 110W by performing a flip-chip bonding process. In an example embodiment different from the example embodiment of FIGS. 14 and 15, an insulating member 132 may not be attached on the semiconductor wafer 110W, and may be attached below the second semiconductor die 120 so as to surround the connection members 131 and the second connection pads 126. This second semiconductor die 120 with the insulating member 132 attached thereto may be mounted on the semiconductor wafer 110W, and the connection members 131 connected to the second connection pads 126 of the second semiconductor die 120 may be connected to the first bonding pads 117 of the semiconductor wafer 110W.

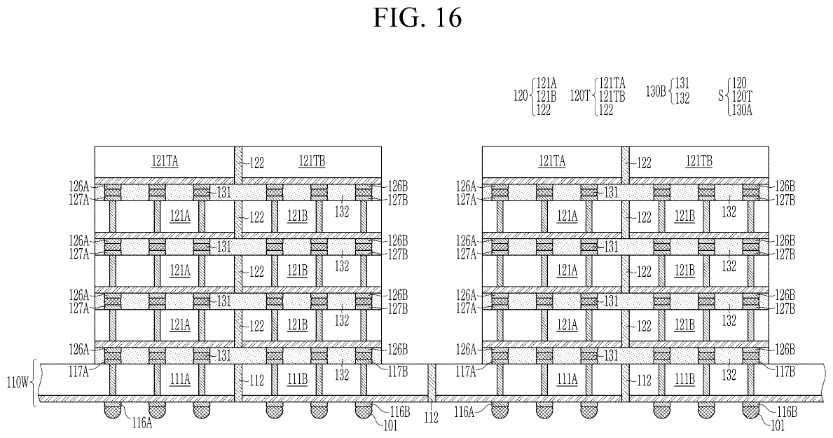

FIG. 16 is a cross-sectional view illustrating an operation of stacking second semiconductor dies 120.

Referring to FIG. 16, the second semiconductor dies 120 may be stacked sequentially from the bottom. The stacking process may be performed by repeating a process of attaching an insulating member 132 to a stacked second semiconductor die 120 and mounting another second semiconductor die 120 to be stacked, on the second semiconductor die 120 with the insulating member 132 attached thereto. In an example embodiment, the second semiconductor dies 120 may be stacked by performing a flip-chip bonding process. In another example embodiment, a process of attaching an insulating member 132 below a second semiconductor die 120 to be stacked and mounting the second semiconductor die 120 with the insulating member 132 attached thereto on another stacked second semiconductor die 120 may be repeatedly performed.

By manufacturing the high bandwidth memory (HBM) by stacking the second semiconductor dies 120 including two or more core dies 121 as described above, it is possible to improve productivity by reducing the turnaround time (TAT) of a die bonding process, which increases linearly depending on the number of core dies 121, while manufacturing the high-capacity high bandwidth memory (HBM).

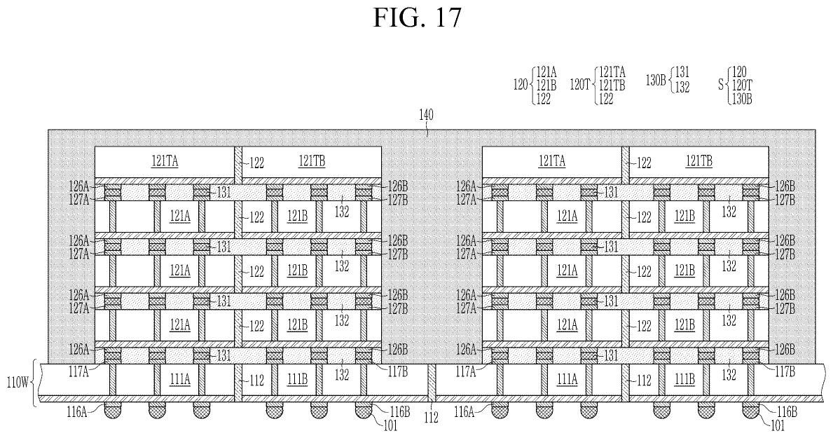

FIG. 17 is a cross-sectional view illustrating an operation of encapsulating semiconductor stacks S on the semiconductor wafer 110W.

Referring to FIG. 17, the semiconductor stacks S may be encapsulated on the semiconductor wafer 110W with the molding material 140. As an example embodiment, the process of performing encapsulating with the molding material 140 may include a compression molding or transfer molding process. In an example embodiment, the molding material 140 may comprise an epoxy molding compound (EMC).

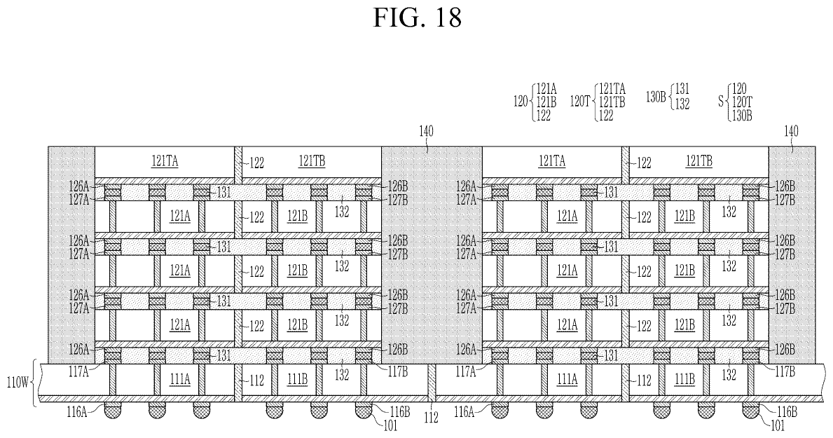

FIG. 18 is a cross-sectional view illustrating an operation of performing a chemical mechanical planarization (CMP) process on the molding material 140.

Referring to FIG. 18, the upper surface of the molding material 140 may be planarized by performing a chemical mechanical planarization (CMP) process. After the chemical mechanical planarization (CMP) process is performed, the upper surface of the second semiconductor die 120T may be exposed. Heat generated by the base die 110 and the second semiconductor dies 120 may be dissipated from the exposed upper surface of the second semiconductor die 120T.

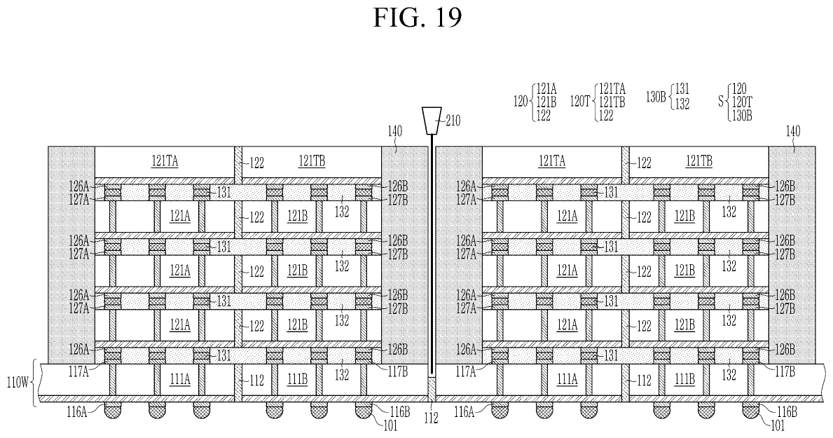

FIG. 19 is a cross-sectional view illustrating a process of singulation of the high bandwidth memory (HBM) 100B from the reconfigured semiconductor wafer 110W.

Referring to FIG. 19, singulation of the high bandwidth memory (HBM) 100B from the semiconductor wafer 110W may be performed using singulation equipment 210. In an example embodiment, as the singulation equipment 210, a blade, a laser, or plasma equipment may be used.

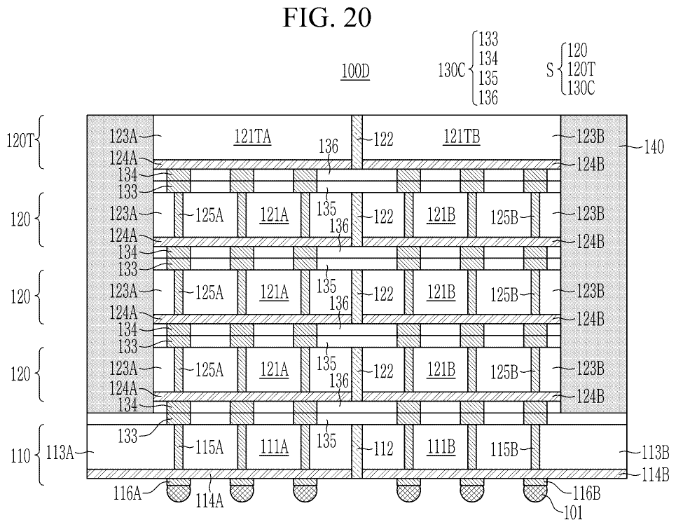

FIG. 20 is a cross-sectional view illustrating a high bandwidth memory (HBM) 100D of an example embodiment.

Referring to FIG. 20, a semiconductor stack S of the high bandwidth memory (HBM) 100D may include second semiconductor dies 120 and inter-connection structures 130C. Each of the inter-connection structures 130C may be disposed between the base die 110 and a second semiconductor die 120 or between neighboring second semiconductor dies 120. The inter-connection structures 130C may couple the base die 110 and a second semiconductor die 120 and couple neighboring second semiconductor dies 120, by hybrid bonding. Hybrid bonding is bonding semiconductor dies by a method of fusing the same material of the semiconductor dies using the bonding property of the same material. Here, the hybrid bonding means performing two different types of bonding, for example, bonding semiconductor dies by a first type of metal-to-metal bonding and a second type of nonmetal-to-nonmetal bonding. By the hybrid bonding, it is possible to form input/output terminals with a ultra-fine pitch.

Each of the inter-connection structures 130C may include first conductive pads 133, second conductive pads 134, a first silicon insulating layer 135, and a second silicon insulating layer 136. The first conductive pads 133 may be disposed on the upper surface of the base die 110, or the upper surface of each of the second semiconductor dies 120 except for the second semiconductor die 120T positioned at the top. The first conductive pads 133 may pass through the first silicon insulating layer 135. The second conductive pads 134 may be disposed on the lower surface of each of the second semiconductor dies 120 and on the first conductive pads 133. The second conductive pads 134 may pass through the second silicon insulating layer 136. The first silicon insulating layer 135 may be disposed on the upper surface of the base die 110 and the upper surface of each of the second semiconductor dies 120 except for the second semiconductor die 120T positioned at the top. The first silicon insulating layer 135 may surround and insulate the first conductive pads 133. The second silicon insulating layer 136 may be disposed on the lower surface of each of the second semiconductor dies 120 and the upper surface of the first silicon insulating layer 135. The second silicon insulating layer 136 may surround and insulate the second conductive pads 134.

Each of the first conductive pads 133 may be bonded directly to the corresponding second conductive pad 134 of second conductive pads 134, by metal-to-metal bonding of the hybrid bonding. By the metal-to-metal bonding of the hybrid bonding, metallic bonds are formed at the interfaces between the first conductive pads 133 and the second conductive pads 134. In an example embodiment, each of the first conductive pads 133 and the second conductive pads 134 may comprise copper. In another example embodiment, the first conductive pads 133 and the second conductive pads 134 may be a metallic material to which hybrid bonding can be applied. The first conductive pads 133 and the second conductive pads 134 may be formed of the same material such that after hybrid bonding, the interfaces between the first conductive pads 133 and the second conductive pads 134 disappear. Through the first conductive pads 133 and the second conductive pads 134, the base die 110 and each of the first core dies 121, or the base die 110 and each of the second core dies 121 may be electrically connected to each other.

The first silicon insulating layers 135 may be directly bonded to the second silicon insulating layers 136 by nonmetal-to-nonmetal bonding of the hybrid bonding. By the nonmetal-to-nonmetal bonding of the hybrid bonding, covalent bonds are formed at the interfaces between the first silicon insulating layer 135 and the second silicon insulating layer 136. In an example embodiment, each of the first silicon insulating layer 135 and the second silicon insulating layer 136 may comprise an inorganic material. In an example embodiment, each of the first silicon insulating layer 135 and the second silicon insulating layer 136 may comprise a silicon oxide, a TEOS formed oxide, a silicon nitride, a silicon oxynitride, or any other appropriate dielectric material. In an example embodiment, each of the first silicon insulating layer 135 and the second silicon insulating layer 136 may comprise SiO₂, SiN, or SiCN. The first silicon insulating layer 135 and the second silicon insulating layer 136 may be formed of the same material such that after hybrid bonding, the interfaces between the first silicon insulating layer 135 and the second silicon insulating layer 136 disappear.

In respect to the high bandwidth memory (HBM) 100D of FIG. 20 other than the above contents, the contents described with respect to the high bandwidth memory (HBM) 100A of FIG. 1 may be applied.

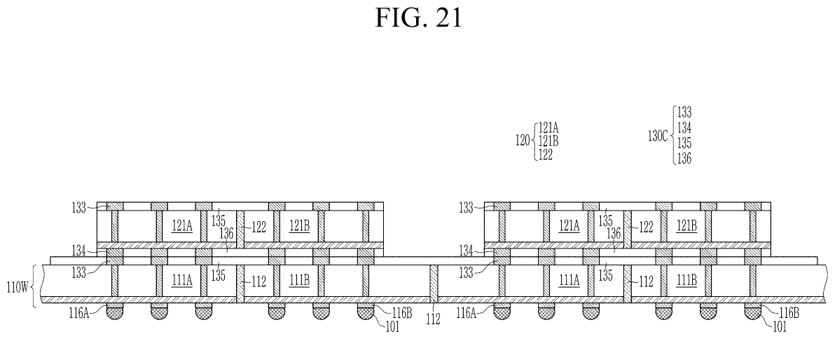

FIGS. 21 to 25 are cross-sectional views for explaining a method of manufacturing the high bandwidth memory (HBM) 100D of FIG. 20.

FIG. 21 is a cross-sectional view illustrating an operation of mounting second semiconductor dies 120 on a semiconductor wafer 110W.

Referring to FIG. 21, the second semiconductor dies 120 may be mounted on the semiconductor wafer 110W by a hybrid bonding process. Before the hybrid bonding, a chemical mechanical planarization (CMP) process may be performed. In an example embodiment, the surface roughness of each of the bonding surfaces where hybrid bonding occurs may be about 10 Å or less. Subsequently, the bonding surface of the first silicon insulating layer 135 on the semiconductor wafer 110W and the bonding surface of the second silicon insulating layer 136 below the second semiconductor die 120 may be activated. In an example embodiment, surface processing may be performed on the bonding surface of the first silicon insulating layer 135 and the bonding surface of the second silicon insulating layer 136 by plasma activation. Next, the semiconductor wafer 110W and the second semiconductor die 120 may be aligned for hybrid bonding. Subsequently, the activated bonding surface of the first silicon insulating layer 135 on the semiconductor wafer 110W and the activated bonding surface of the second silicon insulating layer 136 below the second semiconductor die 120 may be brought into contact with each other and pre-bonded.

Thereafter, the semiconductor wafer 110W and the second semiconductor die 120 are bonded by hybrid bonding. First, the first silicon insulating layer 135 on the semiconductor wafer 110W and the second silicon insulating layer 136 below the second semiconductor die 120 may be bonded by a treatment. The treatment may strengthen the bonding of the first silicon insulating layer 135 on the semiconductor wafer 110W and the second silicon insulating layer 136 below the second semiconductor die 120 pre-bonded.

Subsequently, each of the first conductive pads 133 on the semiconductor wafer 110W are bonded to the corresponding second conductive pad 134 of the second conductive pads 134 of the second semiconductor die 120, by annealing.

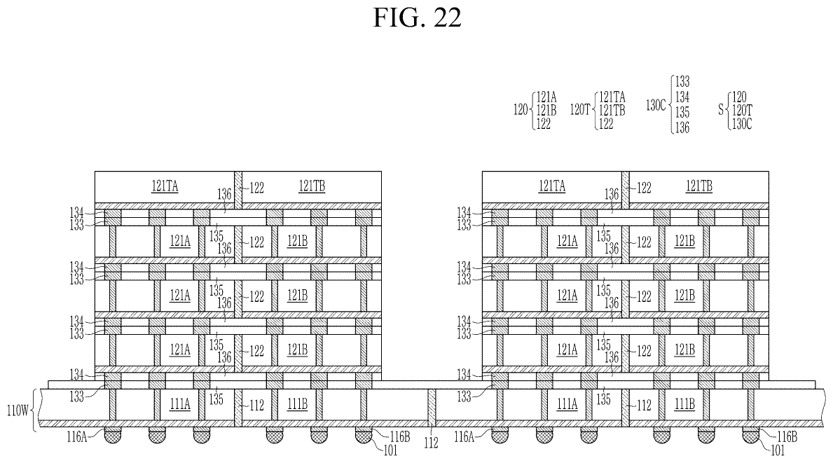

FIG. 22 is a cross-sectional view illustrating an operation of stacking second semiconductor dies 120.

Referring to FIG. 22, the second semiconductor dies 120 may be stacked sequentially from the bottom by performing a hybrid bonding process. In respect to the contents about the hybrid bonding process, the contents described with reference to FIG. 21 may be equally applied.

By manufacturing the high bandwidth memory (HBM) by stacking the second semiconductor dies 120 including two or more core dies 121 as described above, it is possible to improve productivity by reducing the turnaround time (TAT) of a die bonding process, which increases linearly depending on the number of core dies 121, while manufacturing the high-capacity high bandwidth memory (HBM).

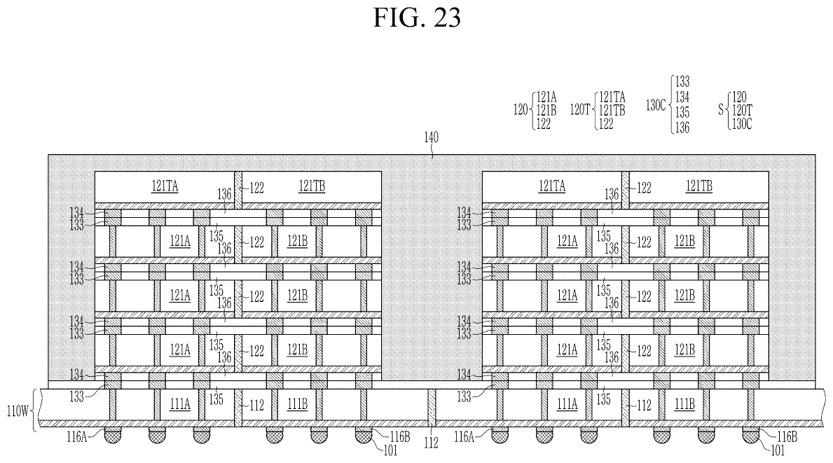

FIG. 23 is a cross-sectional view illustrating an operation of encapsulating semiconductor stacks S on the semiconductor wafer 110W.

Referring to FIG. 23, the semiconductor stacks S may be encapsulated on the semiconductor wafer 110W with the molding material 140. As an example embodiment, the process of performing encapsulating with the molding material 140 may include a compression molding or transfer molding process. In an example embodiment, the molding material 140 may comprise an epoxy molding compound (EMC).

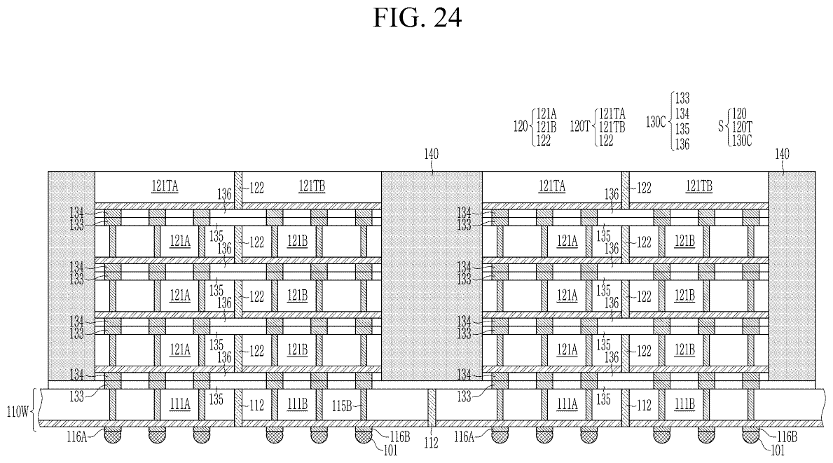

FIG. 24 is a cross-sectional view illustrating an operation of performing a chemical mechanical planarization (CMP) process on the molding material 140.

Referring to FIG. 24, the upper surface of the molding material 140 may be planarized by performing a chemical mechanical planarization (CMP) process. After the chemical mechanical planarization (CMP) process is performed, the upper surface of the second semiconductor die 120T may be exposed. Heat generated by the base die 110 and the second semiconductor dies 120 may be dissipated from the exposed upper surface of the second semiconductor die 120T.

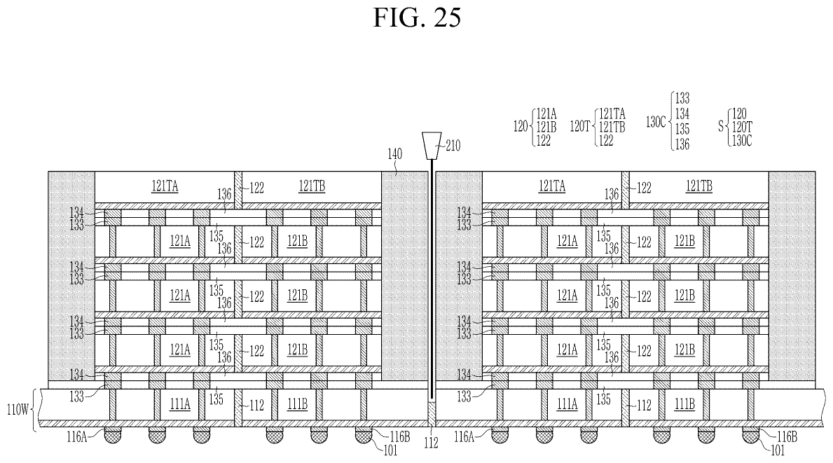

FIG. 25 is a cross-sectional view illustrating a process of singulation of the high bandwidth memory (HBM) 100D from the reconfigured semiconductor wafer 110W.

Referring to FIG. 25, singulation of the high bandwidth memory (HBM) 100D from the semiconductor wafer 110W may be performed using singulation equipment 210. In an example embodiment, as the singulation equipment 210, a blade, a laser, or plasma equipment may be used.

While embodiments of inventive concepts have been described in connection with the presented embodiments, it is to be understood that inventive concepts are not limited to the disclosed embodiments. On the contrary, inventive concepts are intended to cover various modifications and equivalent arrangements included within the spirit and scope of the appended claims.

What is claimed is:

1. A high bandwidth memory comprising:
a base die; and
a semiconductor stack on the base die, wherein
the semiconductor stack includes a plurality of semiconductor dies, which are stacked in a vertical direction, and
each of the plurality of semiconductor dies includes a plurality of memory dies arranged in a horizontal direction.

2. The high bandwidth memory of claim 1, wherein
each of the plurality of semiconductor dies includes one or more scribe lanes arranged alternately with the plurality of memory dies in the horizontal direction.

3. The high bandwidth memory of claim 1, wherein
the base die is configured to control the plurality of memory dies.

4. The high bandwidth memory of claim 1, wherein
the plurality of memory dies of each of the plurality of semiconductor dies are electrically disconnected from one another.

5. The high bandwidth memory of claim 1, wherein
the plurality of memory dies of each of the plurality of semiconductor dies are thermally connected to each other.

6. The high bandwidth memory of claim 1, wherein
the plurality of memory dies of each of the plurality of semiconductor dies are arranged in a line.

7. The high bandwidth memory of claim 1, wherein
the plurality of memory dies of each of the plurality of semiconductor dies are arranged in two or more lines.

8. The high bandwidth memory of claim 1, wherein
the plurality of memory dies each include a DRAM.

9. A high bandwidth memory comprising:
a first semiconductor die including a first buffer die and a second buffer die that are arranged in a horizontal direction; and
a semiconductor stack on the first semiconductor die, wherein
the semiconductor stack includes a plurality of second semiconductor dies stacked in a vertical direction,
each of the plurality of second semiconductor dies includes a first core die on the first buffer die and a second core die on the second buffer die.

10. The high bandwidth memory of claim 9, wherein
the first semiconductor die includes a scribe lane between the first buffer die and the second buffer die.

11. The high bandwidth memory of claim 9, wherein
the first buffer die and the second buffer die are electrically disconnected from each other.

12. The high bandwidth memory of claim 9, wherein
the first buffer die and the second buffer die are thermally connected to each other.

13. The high bandwidth memory of claim 9, wherein
the first buffer die is electrically connected to the first core die, and
the second buffer die is electrically connected to the second core die.

14. The high bandwidth memory of claim 9, wherein
the first buffer die is electrically disconnected from the second core die, and
the second buffer die is electrically disconnected from the first core die.

15. The high bandwidth memory of claim 9, wherein
the first buffer die is configured to control the first core die, and
the second buffer die is configured to control the second core die.

16. A high bandwidth memory comprising:
a first semiconductor die including a first buffer die and a second buffer die, which are arranged in a horizontal direction; and
a semiconductor stack on the first semiconductor die,
wherein the semiconductor stack includes a plurality of second semiconductor dies stacked in a vertical direction, a plurality of inter-connection structures stacked alternately with the plurality of second semiconductor dies, and a molding material covering the semiconductor stack,
wherein the molding material is on the first semiconductor die,
wherein each of the plurality of second semiconductor dies includes a first core die on the first buffer die and a second core die on the second buffer die.

17. The high bandwidth memory of claim 16, wherein
each of the plurality of inter-connection structures includes a plurality of micro bumps and an insulating member insulating the plurality of micro bumps.

18. The high bandwidth memory of claim 17, wherein
the insulating member includes a non-conductive film or molded underfill (MUF).

19. The high bandwidth memory of claim 16, wherein each of the plurality of inter-connection structures includes:
a plurality of first conductive pads;
a first silicon insulating layer insulating the plurality of first conductive pads;
a plurality of second conductive pads on the plurality of first conductive pads and bonded directly to a corresponding first conductive pad of the plurality of first conductive pads; and
a second silicon insulating layer on the first silicon insulating layer and bonded directly to the first silicon insulating layer.

20. The high bandwidth memory of claim 16, wherein
the first core die and the second core die each include a plurality of through-vias.
